(19) United States
(12) Patent Application Publication
(10) Pub. No.: US 2025/0140771 A1
(43) Pub. Date: May 1, 2025

(54) SEMICONDUCTOR PACKAGE INCLUDING A CORE LAYER

(71) Applicant: SAMSUNG ELECTRONICS CO., LTD., SUWON-SI (KR)

(72) Inventors: Dahee Kim, Suwon-si (KR); Taehoon Lee, Suwon-si (KR); Gyujin Choi, Suwon-si (KR)

(21) Appl. No.: 18/668,868

(22) Filed: May 20, 2024

(30) Foreign Application Priority Data
Oct. 30, 2023 (KR) 10-2023-0147060

(51) Int. Cl. H01L 25/18; H01L 21/48; H01L 23/00; H01L 23/31; H01L 23/367; H01L 23/498

(52) U.S. Cl. CPC H01L 25/18; H01L 23/3128; H01L 23/3677; H01L 23/49833; H01L 23/49838; H01L 24/16; H01L 24/32; H01L 24/73; H01L 21/4853; H01L 24/48; H01L 2224/16235; H01L 2224/32145; H01L 2224/32225; H01L 2224/48147; H01L 2224/48227; H01L 2224/73253; H01L 2224/73265; H01L 2225/06506; H01L 2225/0651; H01L 2225/06562; H01L 2225/06589; H01L 2924/1815

(57) ABSTRACT

A semiconductor package using a core layer to reduce the total thickness of the semiconductor package and to maximize heat dissipation characteristics is provided. The semiconductor package includes a first redistribution layer, a first semiconductor device disposed on the first redistribution layer, a second semiconductor device disposed on the first redistribution layer and adjacent to the first semiconductor device, a support member disposed at side surfaces of the first semiconductor device and the second semiconductor device, a third semiconductor device disposed above the second semiconductor device, and a heat dissipation structure disposed above the first semiconductor device and adjacent to the third semiconductor device.

### CROSS-REFERENCE TO RELATED APPLICATION

This application is based on and claims priority under 35 U.S.C. § 119 to Korean Patent Application No. 10-2023-0147060, filed on Oct. 30, 2023, in the Korean Intellectual Property Office, the disclosure of which is incorporated by reference herein in its entirety.

### BACKGROUND

### 1. Technical Field

The inventive concept relates to a semiconductor package, and more particularly, to a semiconductor package including a core layer.

### 2. Discussion of Related Art

In response to the rapid development of the electronics industry and the demands of users, electronic devices are becoming smaller and faster. As electronic devices become smaller and faster, semiconductor packages used therein are also becoming higher-density and higher performance. Meanwhile, the semiconductor packages need to secure high reliability along with high performance and large capacity. As performance and capacity of semiconductor packages increase, power consumption of semiconductor packages may increase. Accordingly, as development of the semiconductor packages continues, research is being conducted on package structures that may maximize heat dissipation characteristics in response to high performance and high capacity semiconductor packages.

### SUMMARY

The inventive concept relates to a semiconductor package using a core layer having a reduced overall thickness and improved heat dissipation characteristics.

In addition, objectives and implementations of the of the inventive concept are not limited to those mentioned herein, and other objectives and implementations will be clearly understood by those skilled in the art from the following description.

According to an aspect of the inventive concept, there is provided a semiconductor package including a first redistribution layer, a first semiconductor device disposed on the first redistribution layer, a second semiconductor device disposed on the first redistribution layer to be adjacent to the first semiconductor device, a support member disposed at side surfaces of the first semiconductor device and the second semiconductor device, a third semiconductor device disposed above the second semiconductor device, and a heat dissipation structure disposed above the first semiconductor device to be adjacent to the third semiconductor device.

According to another aspect of the inventive concept, there is provided a semiconductor package including a first redistribution layer, a first semiconductor device disposed on the first redistribution layer, a second semiconductor device disposed on the first redistribution layer and adjacent to the first semiconductor device, a support member disposed at side surfaces of the first semiconductor device and the second semiconductor device, a second redistribution layer disposed on the first semiconductor device, the second semiconductor device, and the support member, a third semiconductor device disposed on the second redistribution layer on the second semiconductor device, and a heat dissipation structure disposed on the second redistribution layer above at least a part of the first semiconductor device and adjacent to the third semiconductor device. The support member includes a through-hole region exposing the first redistribution layer, and a groove region including a depression in the support member, and the first semiconductor device is disposed in the through-hole region and the second semiconductor device is disposed in the groove region.

According to another aspect of the inventive concept, there is provided a semiconductor package including a first redistribution layer, a first semiconductor device disposed on the first redistribution layer, a second semiconductor device disposed on the first redistribution layer to be adjacent to the first semiconductor device, a support member including a through-hole region in which the first semiconductor device is disposed and a groove region in which the second semiconductor device is disposed, a third semiconductor device disposed above the second semiconductor device, and a heat dissipation structure disposed above at least a part of the first semiconductor device and adjacent to the third semiconductor device. The through-hole region exposes the first redistribution layer, and the groove region includes a depression in the support member and having a width that increases as a distance from the support member increases.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIGS. 2A to 2C are cross-sectional views illustrating a structure of a memory device in the semiconductor package of FIG. 1 in more detail;

FIG. 3A and FIG. 3B are cross-sectional views of semiconductor packages according to embodiments;

FIG. 4A and FIG. 4B are cross-sectional views of semiconductor packages according to embodiments;

FIG. 5 is a cross-sectional view of a semiconductor package according to an embodiment;

FIGS. 6A to 6G are cross-sectional views schematically illustrating processes of a method of manufacturing a semiconductor package, according to an embodiment; and

FIG. 7A and FIG. 7B are cross-sectional views schematically illustrating processes of a method of manufacturing a semiconductor package, according to an embodiment.

### DETAILED DESCRIPTION OF THE EMBODIMENTS

Hereinafter, embodiments of the inventive concept will be described in detail with reference to the accompanying drawings. Like reference numerals refer to like elements, and their repetitive descriptions may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

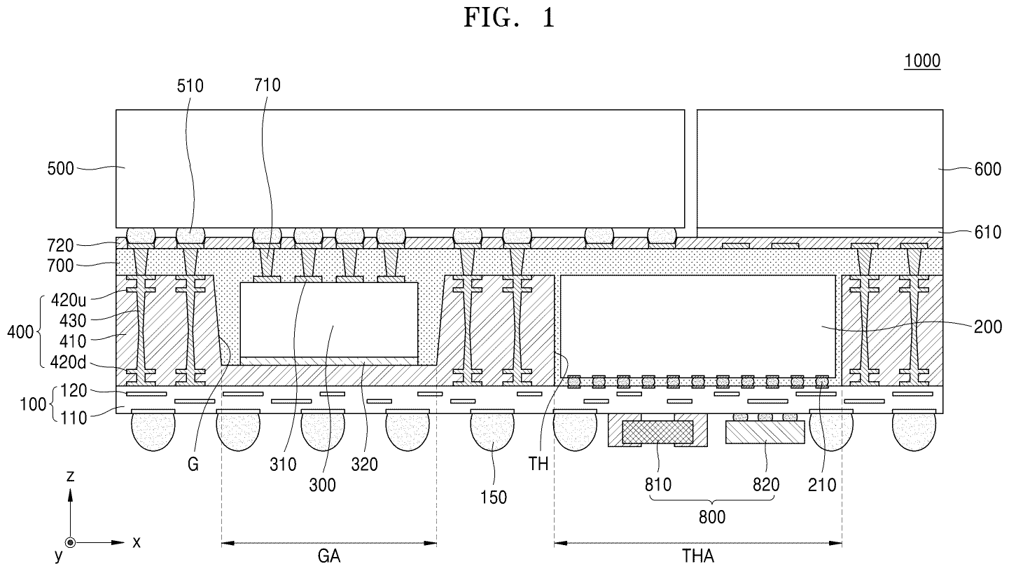

FIG. 1 is a cross-sectional view of a semiconductor package 1000 according to an embodiment.

Referring to FIG. 1, the semiconductor package 1000 may include a first redistribution layer 100, a first semiconductor device 200, a second semiconductor device 300, a core layer 400, a third semiconductor device 500, a heat dissipation structure 600, and a sealant 700.

The first redistribution layer 100 may be disposed under the first semiconductor device 200, the second semiconductor device 300, and a core layer 400. The first redistribution layer 100 may redistribute signals of the first semiconductor device 200 mounted on the first redistribution layer 100 to an external region of the semiconductor chip. The first semiconductor device 200 may be, for example, a semiconductor chip. More specifically, the first redistribution layer 100 may include a first body insulating layer 110 and first redistribution lines 120. The first redistribution lines 120 may be disposed in the first body insulating layer 110. The first redistribution lines 120 may include multiple layers, and the first redistribution lines 120 of different layers may be connected to one another by vias.

The first body insulating layer 110 may include an insulating material, for example, photo-imageable dielectric (PID) resin. In addition, the first body insulating layer 110 may further include an inorganic filler. A material of the first body insulating layer 110 is not limited to PID resin. The first body insulating layer 110 may have a multilayer structure, and the multilayer structure of the first body insulating layer 110 may correspond to the multilayer structure of the first redistribution lines 120. In FIG. 1, the first body insulating layer 110 is illustrated as having a single layer structure, however, a multilayer structure may be provided. When the first body insulating layer 110 has a multilayer structure, layers of the first body insulating layer 110 may include a same material or different materials.

External connection pads may be disposed at a bottom surface of the first body insulating layer 110, and external connection terminals 150 may be respectively disposed on the external connection pads. The external connection terminals 150 may be electrically connected to first connection terminals 210 through the first redistribution lines 120 of the first redistribution layer 100. The external connection terminals 150 may be respectively connected to first connection terminals 210. As illustrated in FIG. 1, the external connection pads and the external connection terminals 150 may be disposed at a portion corresponding to a bottom surface of the first semiconductor device 200. The external connection pads and the external connection terminals 150 may be disposed at a portion extending outward in a first direction (x direction) and a second direction (y direction) from the bottom surface of the first semiconductor device 200. For example, the first redistribution layer 100 may distribute signals of the first semiconductor device 200, for example, the semiconductor chip, at the external connection pads disposed in a portion wider than a bottom surface of the semiconductor chip. In this way, a package structure in which the external connection terminals 150 are arranged widely, beyond the bottom surface of the first semiconductor device 200, may be referred to as a fan-out (FO) package structure. In addition, a package structure in which the external connection terminals 150 are arranged only at the bottom surface of the first semiconductor device 200 may be referred to as a fan-in (FI) package structure. For reference, the external connection pads on which the external connection terminals 150 are respectively arranged may be included in the first redistribution lines 120. According to an embodiment, the external connection pads may be separate components from the first redistribution lines 120.

The first semiconductor device 200 may be disposed in a through-hole region THA of the core layer 400. For example, the core layer 400 may surround side surface of the first semiconductor device 200. The through-hole region THA may be defined as a region of a through-hole TH that completely penetrates the core layer 400. The first semiconductor device 200 may be disposed apart from an internal wall of the through-hole TH. The internal wall of the through-hole TH may be vertical or inclined in the z direction. For example, in the case that the internal wall of the through-hole TH is vertical, a width of the through-hole TH may be consistent in the z direction. The sealant 700 may be disposed between the internal wall of the through-hole TH and the first semiconductor device 200. The first connection terminals 210 may electrically connect the first semiconductor device 200 and the first redistribution layer 100. The first connection terminals 210 may completely penetrate a portion of the core layer 400 disposed between the first semiconductor device 200 and the first redistribution layer 100. The first connection terminals 210 may include, for example, pillars and solder. According to an embodiment, the first connection terminals 210 may include only solder.

The first semiconductor device 200 may include, for example, a logic semiconductor chip or a memory semiconductor chip. The logic semiconductor chip may include, for example, an application processor (AP), a microprocessor, a central processing unit (CPU), a controller, or an application specific integrated circuit (ASIC). The memory semiconductor chip may include, for example, volatile memory such as dynamic random access memory (DRAM) or static random access memory (SRAM), or non-volatile memory such as flash memory. In the semiconductor package 1000, the first semiconductor device 200 may include a logic semiconductor chip, for example, an AP chip. In addition, the first semiconductor device 200 may be referred to as a system on chip (SoC) in terms of integrated functions. Hereinafter, for convenience sake, the first semiconductor device 200 is described using a concept of a semiconductor chip.

In the semiconductor package 1000, the first semiconductor device 200 may include chip pads arranged on the bottom surface thereof. Accordingly, the bottom surface of the first semiconductor device 200, on which the chip pads are disposed, may be an active surface, and a top surface opposite to the bottom surface of the first semiconductor device 200 may be an inactive surface. The chip pads may be electrically connected to other components in the first semiconductor device 200, for example, an integrated circuit. Specifically, multiple wiring layers may be formed on the bottom surface of the first semiconductor device 200, and the chip pads may be electrically connected to the internal integrated circuit through the multiple wiring layers.

As illustrated in FIG. 1, the first semiconductor device 200 may be mounted on the first redistribution layer 100 through the first connection terminals 210. Accordingly, the integrated circuit of the first semiconductor device 200 may be connected to the first redistribution lines 120 of the first redistribution layer 100 through the first connection terminals 210. The integrated circuit of the first semiconductor device 200 may also be connected to the external connection terminals 150 through the first redistribution lines 120. In the case that the bottom surface of the first semiconductor device 200 is the active surface, the active surface of the first semiconductor device 200 may face the first redistribution layer 100 therebelow.

The second semiconductor device 300 may be disposed adjacent to the first semiconductor device 200. The second semiconductor device 300 may be disposed at a groove region GA of the core layer 400. The second semiconductor device 300 may be disposed in the groove region GA of the core layer 400. For example, the core layer 400 may surround side surface of the second semiconductor device 300. The groove region GA may be defined as a region in a groove G formed by partially removing an upper portion of the core layer 400. The groove G may be a depression in an upper portion of the core layer 400. The second semiconductor device 300 may be disposed apart from an internal wall of the groove G. The internal wall of the groove G may be inclined or vertical. For example, in a case where the internal wall of the groove G is inclined, the groove G may have a width that increases as a distance from the core layer 400 increases in the z direction. The sealant 700 may be disposed between the internal wall of the groove G and the second semiconductor device 300. Furthermore, the second semiconductor device 300 may be adhered and fixed to the groove region GA through a first adhesive layer 320. That is, the first adhesive layer 320 may be disposed between a bottom surface of the second semiconductor device 300 and the core layer 400 at a bottom surface of the groove G.

The second semiconductor device 300 may include, for example, a logic semiconductor chip or a memory semiconductor chip. In addition, the second semiconductor device 300 may include a package including at least one chip. In the semiconductor package 1000, the second semiconductor device 300 may include, for example, a power management IC (PMIC) package. The second semiconductor device 300 is not limited to the PMIC package. Hereinafter, for convenience sake, the second semiconductor device 300 is described using a concept of a semiconductor chip.

In the semiconductor package 1000, the second semiconductor device 300 may include chip pads disposed on a top surface thereof. Accordingly, the top surface of the second semiconductor device 300, on which the chip pads are arranged, may be an active surface, and a bottom surface opposite to the top surface of the second semiconductor device 300 may be an inactive surface. The chip pads may be electrically connected to other components in the second semiconductor device 300, for example, an integrated circuit.

As illustrated in FIG. 1, the second semiconductor device 300 may be connected to the third semiconductor device 500 through second connection terminals 310 disposed on the top surface thereof. More specifically, the second semiconductor device 300 may be connected to the third semiconductor device 500 through the second connection terminals 310, through electrodes 710, and third connection terminals 510. Here, the through electrodes 710 may penetrate the sealant 700 covering the top surface of the second semiconductor device 300. In addition, the third connection terminals 510 may mount the third semiconductor device 500 on the core layer 400.

In a case that the top surface of the second semiconductor device 300 is the active surface, the active surface of the second semiconductor device 300 may face the third semiconductor device 500 thereabove. Accordingly, in the semiconductor package 1000, the first semiconductor device 200 and the second semiconductor device 300 may be disposed in the core layer 400 with their active surfaces facing opposite directions.

The core layer 400 may include the through-hole region THA completely penetrating the core layer 400 and the groove region GA in which a lower portion of the core layer 400 is maintained. As illustrated in FIG. 1, the through-hole region THA may be formed on a right side of the core layer 400 in the x direction, and the groove region GA may be formed on a left side of the core layer 400 in the x direction. Positions of the through-hole region THA and the groove region GA are not limited thereto. As described herein, the first semiconductor device 200 may be disposed in the through-hole region THA and the second semiconductor device 300 may be disposed in the groove region GA.

The core layer 400 may include a core insulating layer 410, core wirings 420d, 420u, and core vias 430. The core insulating layer 410 may maintain and support the semiconductor package 1000. For example, the core insulating layer 410 may maintain and support an entire structure of the semiconductor package 1000. Accordingly, the core layer 400 may be referred to as a support member due to the function of the core insulating layer 410. The core layer 400 may include, for example, an embedded trace substrate (ETS) core. ETS may be a circuit board including a circuit pattern disposed in an insulating material. In the case of ETS, the number of wiring layers may be reduced by using a prepreg material.

The core insulating layer 410 may include an insulating material, for example, thermosetting resin, such as epoxy resin, or thermoplastic resin, such as polyimide, and may further include an inorganic filler. In addition, the core insulating layer 410 may include resin impregnated into a core material, such as glass fiber, glass cloth, or glass fabric, along with an inorganic filler, such as a prepreg material, AJINOMOTO BUILD-UP FILM® (ABF), FR-4, or Bismaleimide Triazine (BT).

Each of the core wirings 420d, 420u may extend in the x direction and the y direction. Each of the core wirings 420d, 420u may have a multilayer structure. In addition, the core wirings 420d, 420u may include a lower core wiring 420d arranged in a lower portion of the core insulating layer 410 and an upper core wiring 420u arranged in an upper portion of the core insulating layer 410. Each of the core vias 430 may have a structure extending in a z direction. The core vias 430 may connect the lower core wirings 420d and the upper core wirings 420u to each other. In addition, each of the core vias 430 may connect different layers of the lower core wirings 420d arranged in the z direction to each other and may connect different layers of the upper core wirings 420u arranged in the z direction to each other. In addition, the core insulating layer 410 may have a multilayer structure corresponding to the multilayer structure of each of the core wirings 420d, 420u. In FIG. 1, the core insulating layer 410 is illustrated as a single layer, however the core insulating layer 410 may include a multilayer structure.

The third semiconductor device 500 may be disposed on the core layer 400. The third semiconductor device 500 may be disposed on the core layer 400 above the second semiconductor device 300. Specifically, the third semiconductor device 500 may be disposed on the core layer 400 to entirely overlap the second semiconductor device 300 and at least a part of the first semiconductor device 200 in the z direction. The third semiconductor device 500 may be mounted on the core layer 400 through the third connection terminals 510. The third semiconductor device 500 may be connected to the core wirings 420u of the core layer 400 through the third connection terminals 510. In addition, the third semiconductor device 500 may be connected to the second semiconductor device 300 through the third connection terminals 510 and the through electrodes 710.

The third semiconductor device 500 may include a single chip or a package including a plurality of chips. When the third semiconductor device 500 includes the package, the semiconductor package 1000 may correspond to a package on package (POP) structure. For example, in the semiconductor package 1000, the first redistribution layer 100, the first semiconductor device 200, the second semiconductor device 300, the core layer 400, and the sealant 700 may constitute a lower package, and the third semiconductor device 500 may constitute an upper package, so that the semiconductor package 1000 may have the POP structure in which the upper package may be stacked on the lower package.

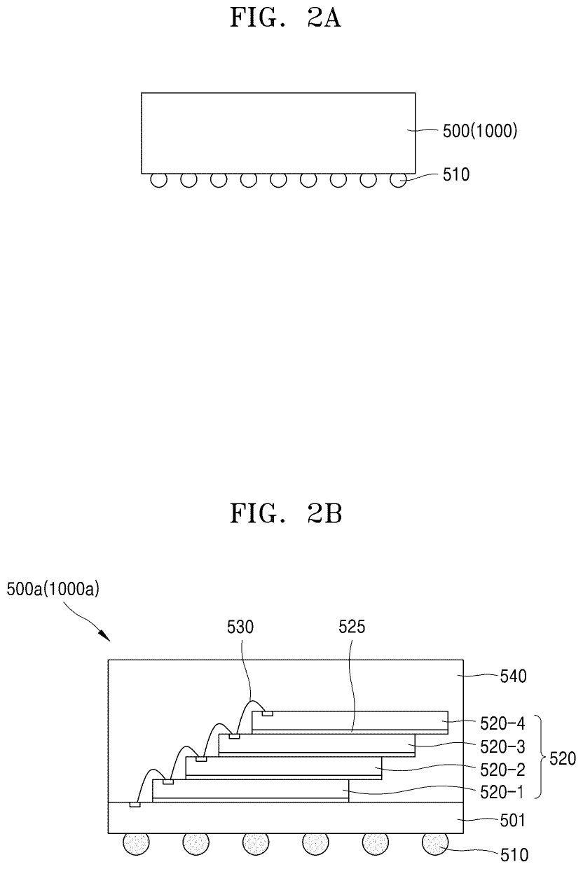

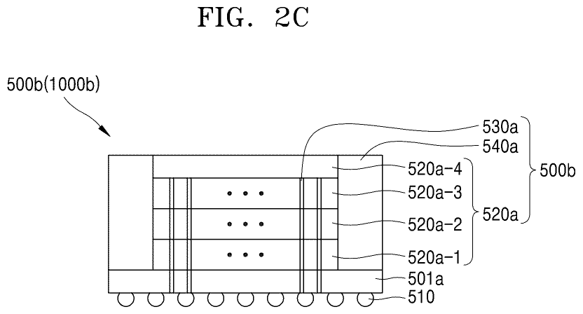

In the semiconductor package 1000, the third semiconductor device 500 may include a memory device. The type of the third semiconductor device 500 is not limited to a memory device. The third semiconductor device 500 may be mounted on the core layer 400 in, for example, a flip-chip bonding structure or a wire bonding structure. Various structures and bonding structures of the third semiconductor device 500 are described in more detail with reference to FIGS. 2A to 2C.

The heat dissipation structure 600 may be disposed adjacent to the third semiconductor device 500. The heat dissipation structure 600 may be disposed on the core layer 400 above the first semiconductor device 200. Specifically, the heat dissipation structure 600 may be disposed on the core layer 400 to overlap at least a part of the first semiconductor device 200 in the z direction. In some embodiments, the heat dissipation structure 600 may be disposed on the core layer 400 to entirely overlap the first semiconductor device 200.

The heat dissipation structure 600 may be formed of a material with high thermal conductivity. The heat dissipation structure 600 may effectively dissipate heat generated by the first semiconductor device 200. The heat dissipation structure 600 may effectively radiate heat generated by the first semiconductor device 200 to an exterior of the semiconductor package 1000. For example, the heat dissipation structure 600 may include silicon, graphite, or metal. The heat dissipation structure 600 may be stacked on the core layer 400 through a second adhesive layer 610. The second adhesive layer 610 may include a material with high thermal conductivity. The second adhesive layer 610 may effectively transfer heat from the first semiconductor device 200 to the heat dissipation structure 600. For example, the second adhesive layer 610 may be formed of a thermal interface material (TIM), thermally conductive resin, thermally conductive polymer, or silicon oxide or silicon nitride such as SiO₂ or SiCN. Here, the TIM may include a material with high thermal conductivity, that is, a material with low thermal resistance, such as grease, tape, an elastomer filling pad, and a phase transition material.

The sealant 700 may seal the first semiconductor device 200 and the second semiconductor device 300. The sealant 700 inhibit or prevent the first semiconductor device 200 and the second semiconductor device 300 from being physically or chemically damaged. Specifically, the sealant 700 may cover side surfaces and the top surface of the first semiconductor device 200, side surfaces and the top surface of the second semiconductor device 300, and a top surface of the core layer 400. For example, the sealant 700 may fill a space between the first semiconductor device 200 and the internal wall of the through-hole TH, and a space between the second semiconductor device 300 and the internal wall of the groove G. Further, the sealant 700 may cover the top surfaces of the first semiconductor device 200 and the second semiconductor device 300 and the top surface of the core layer 400. In some embodiments, the sealant 700 may be formed thin, or may be omitted from the top surfaces of the first semiconductor device 200 and the second semiconductor device 300 and the top surface of the core layer 400.

The sealant 700 may include thermosetting resin, such as epoxy resin, thermoplastic resin, such as polyimide, or resin including a reinforcing material such as an inorganic filler, such as ABF, FR-4, or BT resin. In addition, the sealant 700 may include a molding material such as an epoxy molding compound (EMC) or a photosensitive material such as a photoimageable encapsulant (PIE). The material of the sealant 700 is not limited to the materials described herein.

Connection pads may be disposed on a top surface of the sealant 700. The connection pads may be connected to the core wirings 420 of the core layer 400 through the through electrodes 710. The connection pads may be connected to the second connection terminals 310 of the second semiconductor device 300 through the through electrodes 710. In addition, the connection pads may be connected to the third connection terminals 510 of the third semiconductor device 500. A passivation layer 720 may be disposed on the top surface of the sealant 700, and the connection pads may be exposed from the passivation layer 720. In some embodiments, an upper portion of the sealant 700, on which the through electrodes 710 and the connection pads are arranged, may function as a redistribution layer.

The external connection terminals 150 may be disposed on a bottom surface of the first redistribution layer 100. The external connection terminals 150 may be electrically connected to the first redistribution lines 120. The external connection terminals 150 may connect the semiconductor package 1000 to an electronic device on which the semiconductor package 1000 is mounted. For example, the external connection terminals 150 may connect the semiconductor package 1000 to a main board of an electronic device on which the semiconductor package 1000 is mounted. The external connection terminals 150 may include at least one of conductive materials, for example, solder, tin (Sn), silver (Ag), copper (Cu), or aluminum (Al).

A passive element 800 may be disposed on the bottom surface of the first redistribution layer 100. According to an embodiment, the passive element 800 may be disposed on the top surface of the first redistribution layer 100 or in the first redistribution layer 100. In addition, in some embodiments, the passive element 800 may be arranged in the core layer 400. The passive element 800 may include, for example, a two-terminal element such as a resistor, an inductor, or a capacitor. In the semiconductor package 1000, the passive element 800 may include a multilayer ceramic capacitor (MLCC) 810 and an Si-capacitor 820. The MLCC 810 may include, for example, a land-side capacitor (LSC). The Si-capacitor 820 may include, for example, an integrated stack capacitor (ISC).

The semiconductor package 1000 may include the core layer 400, and the first semiconductor device 200, for example, the SoC, and the second semiconductor device 300, for example, the PMIC package, may be arranged in the through-hole region THA and the groove region GA formed in the core layer 400. In addition, the first semiconductor device 200 and the second semiconductor device 300 may be arranged in the core layer 400 with active surfaces thereof facing opposite directions, and the third semiconductor device 500, for example, a DRAM package, and the heat dissipation structure 600 may be stacked on the second semiconductor device 300 and the first semiconductor device 200. Due to such an example arrangement structure, a degree of freedom in wiring design may be improved in upper and lower portions of the first semiconductor device 200 and the second semiconductor device 300, a thickness of the first redistribution layer 100 may be reduced, and a total thickness of the entire semiconductor package 1000 may be reduced. In addition, a signal path between the first semiconductor device 200, the second semiconductor devices 300, and the third semiconductor device 500 may be reduced, and signal characteristics thereof may be improved. Furthermore, the heat dissipation structure 600 may be stacked on the first semiconductor device 200, and a DRAM package may be arranged similar to an interposer POP (i-POP), and heat dissipation characteristics may be improved, and a supply chain management (SCM) may be stably provided. In a case where the two semiconductor devices (i.e., the first and second semiconductor devices 200 and 300) may be arranged in the core layer 400, chip density in a core layer may be improved along with a sufficient FO function.

FIGS. 2A to 2C are cross-sectional views illustrating a structure of a memory device in the semiconductor package 1000 of FIG. 1.

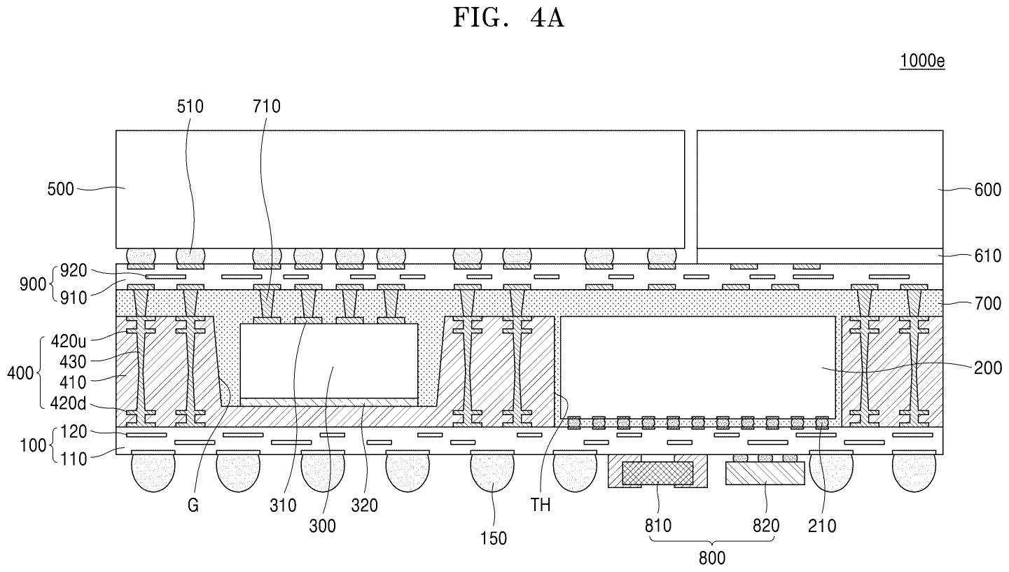

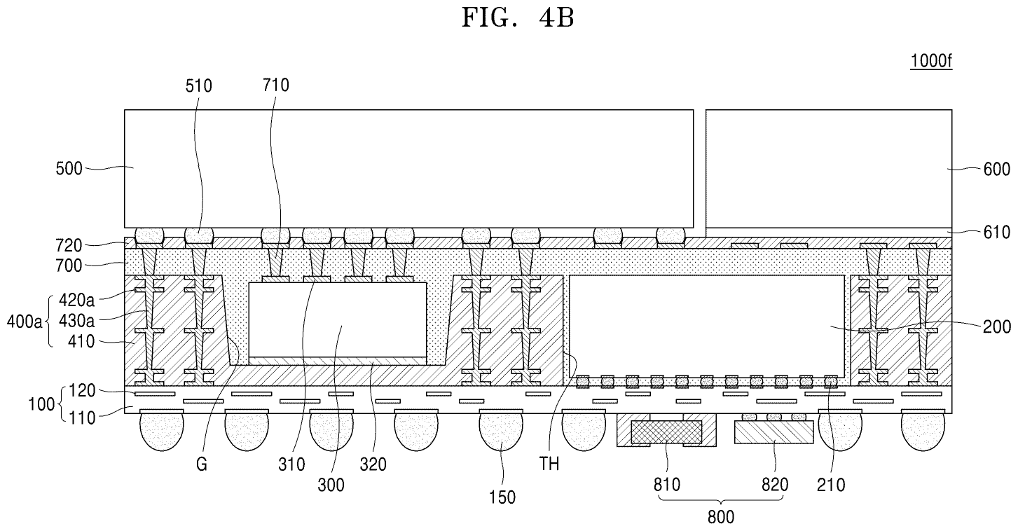

Referring to FIG. 2A, in the semiconductor package 1000 according to an embodiment, the third semiconductor device 500 may have a single memory chip structure. In addition, the third semiconductor device 500 may include a volatile memory device, such as DRAM or SRAM, or a non-volatile memory device, such as flash memory. For example, in the semiconductor package 1000, the third semiconductor device 500 may include a DRAM device. The third semiconductor device 500 in a flip-chip bonding structure using the third connection terminals 510, may be stacked on the core layer 400, the sealant 700 on the core layer 400, or a second redistribution layer (refer to 900 in FIG. 4A).

Referring to FIG. 2B, in a semiconductor package 1000a according to an embodiment, a third semiconductor device 500a may have a package structure. For example, the third semiconductor device 500a may include an upper package substrate 501, a stack of a plurality of memory chips 520, and an upper sealant 540. Here, the plurality of memory chips 520 may include, for example, DRAM devices, respectively. The type of the plurality of memory chips 520 is not limited to DRAM devices.

The plurality of memory chips 520 in a wire bonding structure including adhesive layers 525 and wires 530, may be stacked on the upper package substrate 501. The adhesive layers 525 and wires 530 may physically and electrically connect the memory chips 520 to each other. In FIG. 2B, four memory chips 520-1 to 520-4 are illustrated in a stacked structure. The number of memory chips 520 is not limited to four. For example, three or less memory chips 520, or five or more memory chips 520 may be stacked. In addition, the plurality of memory chips 520 may be stacked in a stepwise structure on the upper package substrate 501. The inventive concept is not limited thereto, and the plurality of memory chips 520 may be stacked on the upper package substrate 501 in a zigzag structure or a combination of a stepwise structure and a zigzag structure.

The third connection terminals 510 may be disposed on a bottom surface of the upper package substrate 501. The third semiconductor device 500a may be stacked on the core layer 400, the sealant 700 on the core layer 400, or the second redistribution layer (refer to 900 in FIG. 4A) through the third connection terminals 510.

Referring to FIG. 2C, in a semiconductor package 1000b according to an embodiment, a third semiconductor device 500b may include a high bandwidth memory (HBM) package. More specifically, the third semiconductor device 500b may include a base chip 501a and a plurality of core chips 520a disposed on the base chip 501a. In addition, the base chip 501a and the plurality of core chips 520a may include through electrodes 530a. For example, the through electrodes 530a may penetrate at least some of the core chips 520S. The through electrodes 530a may not penetrate the uppermost core chip 520a-4 among the plurality of core chips 520a.

The base chip 501a may include logic elements. Accordingly, the base chip 501a may include a logic chip. The base chip 501a may be disposed under the plurality of core chips 520a, and may integrate signals of the plurality of core chips 520a and transmit the signals to the outside. The base chip 501a may transmit signals and power from the outside to the plurality of core chips 520a. Accordingly, the base chip 501a may be referred to as a buffer chip or a control chip. The plurality of core chips 520a may include, for example, DRAM devices, respectively. The type of the plurality of core chips 520a is not limited to DRAM devices. In FIG. 2C, four core chips 520a-1 to 520a-4 are illustrated in a stacked structure. The number of core chips 520a is not limited to four. For example, three or less core chips 520a, or five or more core chips 520a may be stacked.

The third connection terminals 510 may be disposed on a bottom surface of the base chip 501a. The third connection terminals 510 may be connected to the through electrodes 530a. The third semiconductor device 500b may be stacked on the core layer 400, the sealant 700 on the core layer 400, or the second redistribution layer (refer to 900 in FIG. 4A) through the third connection terminals 510. The plurality of core chips 520a on the base chip 501a may be sealed by an upper sealant 540a. An upper surface of the uppermost core chip 520a-4 among the plurality of core chips 520a may not be covered with the upper sealant 540a. For example, at least a portion of the upper surface of the uppermost core chip 520a-4 among the plurality of core chips 520a may be exposed by the upper sealant 540a.

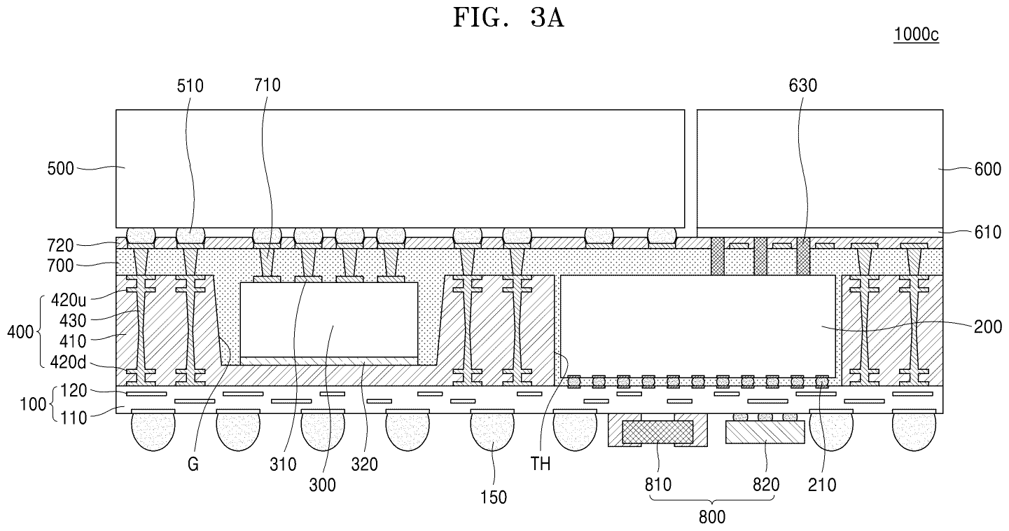

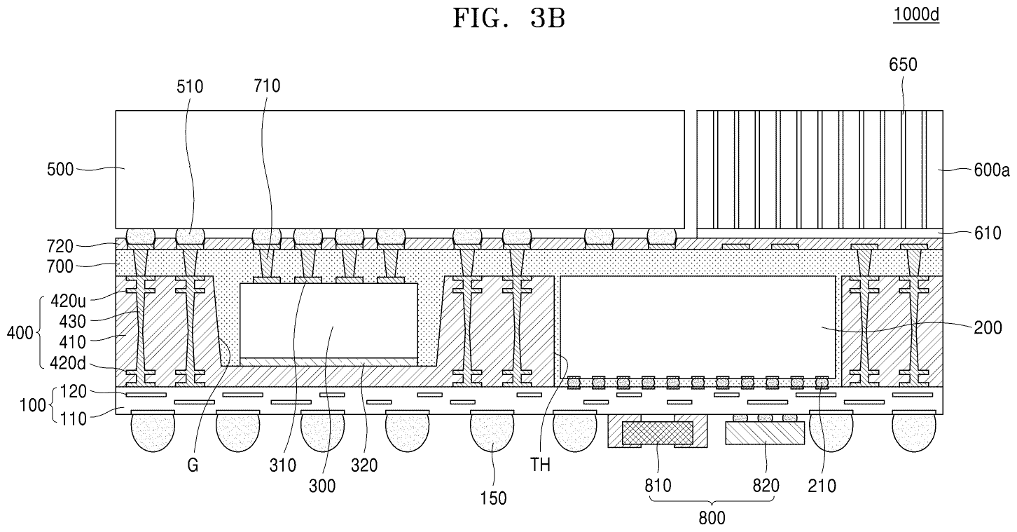

FIG. 3A and FIG. 3B are cross-sectional views of semiconductor packages 1000c and 1000d according to embodiments.

Referring to FIG. 3A, the semiconductor package 1000c according to an embodiment may include heat dissipation vias 630. The heat dissipation vias 630 may be disposed between the first semiconductor device 200 and the heat dissipation structure 600. More specifically, in the semiconductor package 1000ct, the heat dissipation vias 630 may be arranged to penetrate the sealant 700 and the passivation layer 720. In addition, bottom surfaces of the heat dissipation vias 630 may contact the top surface of the first semiconductor device 200, and top surfaces of the heat dissipation vias 630 may contact the second adhesive layer 610. In some embodiments, the top surfaces of the heat dissipation vias 630 may contact a bottom surface of the heat dissipation structure 600. The heat dissipation vias 630 may include a material with high thermal conductivity, for example, metal such as Cu, nickel (Ni), Al, Sn, gold (Au), or Ag.

The semiconductor package 1000c includes the heat dissipation vias 630 so that heat generated by the first semiconductor device 200 may be more effectively transmitted to the heat dissipation structure 600. Accordingly, heat dissipation characteristics of the heat dissipation structure 600 may be improved, and as a result, thermal characteristics of the semiconductor package 1000c may be improved, thereby improving reliability of semiconductor devices.

Referring to FIG. 3B, the semiconductor package 1000d according to an embodiment may include a heat dissipation structure 600a. The heat dissipation structure 600a may be formed of, for example, Si. and The heat dissipation structure 600a may include a plurality of metal lines 650. More specifically, in the semiconductor package 1000d, the heat dissipation structure 600a may be manufactured as an Si semiconductor chip. In addition, the heat dissipation structure 600a may include the plurality of metal lines 650 to improve heat dissipation characteristics. The plurality of metal lines 650 may penetrate the heat dissipation structure 600a in a vertical direction. The plurality of metal lines 650 may include metal with high thermal conductivity. For example, the plurality of metal lines 650 may include Cu, Ni, Al, Sn, Au, or Ag. In the semiconductor package 1000d, the heat dissipation structure 600a may include the plurality of metal lines 650, and heat generated by the first semiconductor device 200 may be effectively dissipated through the plurality of metal lines 650 of the heat dissipation structure 600a.

FIG. 4A and FIG. 4B are cross-sectional views of semiconductor packages 1000e and 1000f according to embodiments.

Referring to FIG. 4A, the semiconductor package 1000e according to an embodiment may include a second redistribution layer 900. Specifically, in the semiconductor package 1000e, the second redistribution layer 900 may be disposed on the sealant 700. The second redistribution layer 900 may be electrically connected to the second semiconductor device 300 and the first redistribution layer 100 through the through electrodes 710 of the sealant 700 and the core wirings 420 and the core vias 430 of the core layer 400.

The second redistribution layer 900 may include a second body insulating layer 910 and second redistribution lines 920. The second redistribution lines 920 may include multiple layers, and the second redistribution lines 920 of different layers may be connected to one another by vias. Structures and materials of the second body insulating layer 910 and the second redistribution lines 920 may be the same as those described with respect to the first body insulating layer 110 and the first redistribution lines 120 of the semiconductor package 1000 of FIG. 1.

Connection pads may be disposed on top and bottom surfaces of the second redistribution layer 900. For example, lower connection pads may be disposed on the bottom surface of the second redistribution layer 900, and the through electrodes 710 may be coupled to the lower connection pads. In addition, upper connection pads may be disposed on the top surface of the second redistribution layer 900, and the third connection terminals 510 may be coupled to the upper connection pads. The connection pads may be included in the second redistribution lines 920. In some embodiments, the connection pads may be treated as components different from the second redistribution lines 920.

Referring to FIG. 4B, the semiconductor package 1000f according to embodiment may include a structure of core wirings 420a of a core layer 400a. Specifically, in the semiconductor package 1000f, the core layer 400a may include a core insulating layer 410, the core wirings 420a, and core vias 430a. Each of the core wirings 420a may have a multilayer structure. The core vias 430a may connect the core wirings 420a of different layers. The core wirings 420a may not be divided into upper core wirings and lower core wirings, and may be arranged in the middle of the core insulating layer 410. In addition, the core vias 430a may have relatively small lengths and may connect the core wirings 420a of different layers to one another.

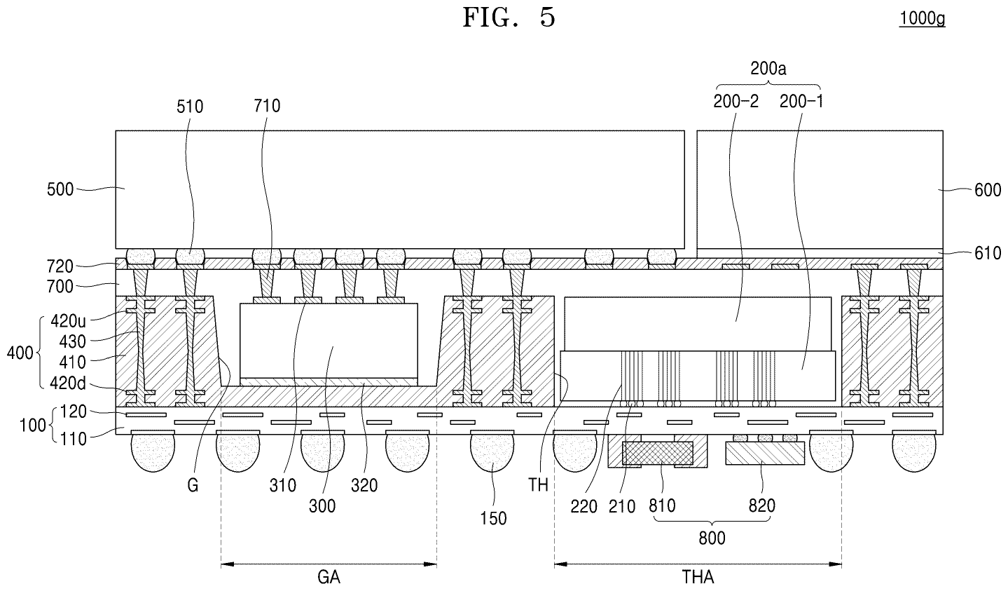

FIG. 5 is a cross-sectional view of a semiconductor package 1000g according to an embodiment.

Referring to FIG. 5, the semiconductor package 1000g according to an embodiment may include a structure of a first semiconductor device 200a. Specifically, in the semiconductor package 1000g, the first semiconductor device 200a may be arranged in a through-hole region THA and may include a first semiconductor chip 200-1 and a second semiconductor chip 200-2.

The first semiconductor chip 200-1 may be disposed on the first redistribution layer 100 through the first connection terminals 210. The first semiconductor chip 200-1 may include an analog chip. For example, the first semiconductor chip 200-1 may include a modem chip, which may support communication of the second semiconductor chip 200-2. The type of the first semiconductor chip 200-1 is not limited to a modem chip. For example, the first semiconductor chip 200-1 may include various types of integrated elements, which may support an operation of the second semiconductor chip 200-2. The first semiconductor chip 200-1 may include a multi-channel I/O interface for exchanging memory signals with the third semiconductor device 500.

The first semiconductor chip 200-1 may include a substrate and through chip electrodes 220. The substrate may constitute a body of the first semiconductor chip 200-1 and may include silicon. The substrate may include an integrated circuit layer and multiple wiring layers. The multiple wiring layers may be arranged at the lowermost portion of the substrate and may be connected to the first connection terminals 210. The integrated circuit layer may be disposed on the multiple wiring layers in the substrate. The through chip electrodes 220 may connect the second semiconductor chip 200-2 to the first connection terminals 210. The through chip electrodes 220 may penetrate the substrate. The through chip electrodes 220 penetrate the Si substrate, and the through chip electrodes 220 may be referred to as through silicon vias (TSVs).

In the first semiconductor chip 200-1, a bottom surface may be an active surface and a top surface may be an inactive surface. Chip pads connected to the multiple wiring layers may be formed on the active surface. The first semiconductor chip 200-1 may be disposed on the first redistribution layer 100 in a flip-chip structure through the first connection terminals 210 disposed on the chip pads.

The second semiconductor chip 200-2 may include a plurality of logic elements. Here, the logic element may refer to an element that performs various signal processing, including logic circuits such as an AND logic gate, an OR logic gate, a NOT logic gate, or a flip-flop. In the semiconductor package 1000g, the second semiconductor chip 200-2 may include, for example, an AP chip. The second semiconductor chip 200-2 may be referred to as a control chip, a process chip, or a CPU chip depending on a function thereof.

The second semiconductor chip 200-2 may be directly stacked on the first semiconductor chip 200-1 to form a stacked chip structure. With the stacked chip structure, the first semiconductor chip 200-1 and the second semiconductor chip 200-2 may be mounted together on the first redistribution layer 100. In the stacked chip structure, the second semiconductor chip 200-2 may be disposed on the first semiconductor chip 200-1 through bonding using fine bumps, pad-to-pad bonding, hybrid bonding (HB), or bonding using an anisotropic conductive film (ACF). Pads may be formed of Cu, and pad-to-pad bonding may be referred to as Cu-to-Cu bonding. HB may mean a combination of pad-to-pad bonding and insulator-to-insulator bonding. An ACF may conduct electricity in only one direction. For example, ACF may refer to a conductive film made by mixing fine conductive particles with adhesive resin to form a film. In some embodiments, the first semiconductor device 200a may have a structure in which the first semiconductor chip 200-1 and the second semiconductor chip 200-2 are sealed together with an internal sealant.

For reference, the first semiconductor device 200 of the semiconductor package 1000 of FIG. 1 may correspond to a monolithic chip in which logic elements are integrated together. In the semiconductor package 1000g, the first semiconductor device 200a may include two semiconductor chips (the first semiconductor chip 200-1 and the second semiconductor chip 200-2) manufactured separately, and which may have different functions. For example, the second semiconductor chip 200-2 may include logic elements other than logic elements of the first semiconductor chip 200-1 in the first semiconductor device 200 of the semiconductor package 1000 of FIG. 1. In the semiconductor package 1000g, the first semiconductor device 200a may correspond to a chiplet structure in which semiconductor chips manufactured by function are combined.

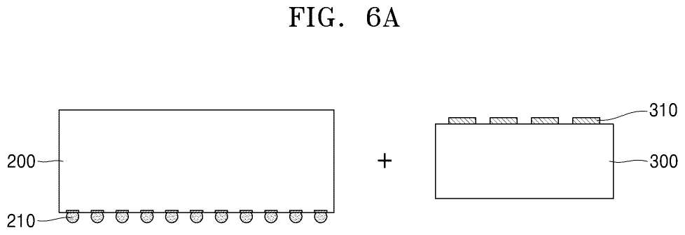

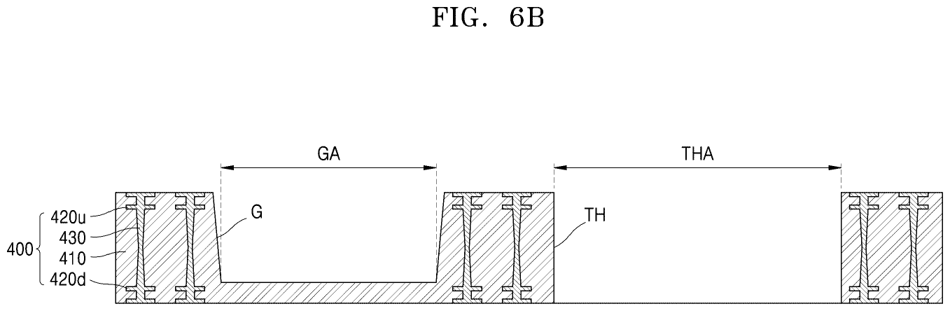

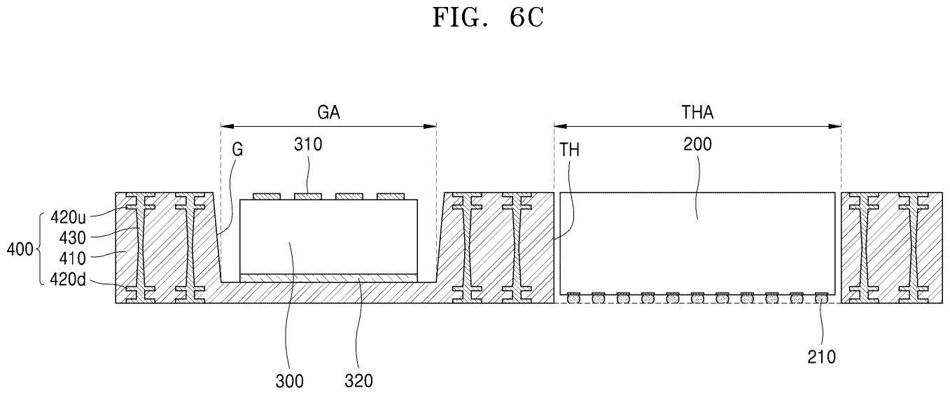

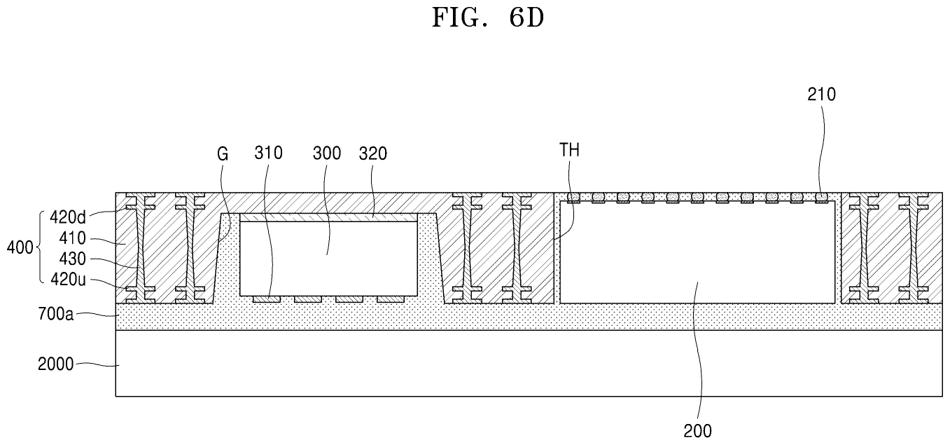

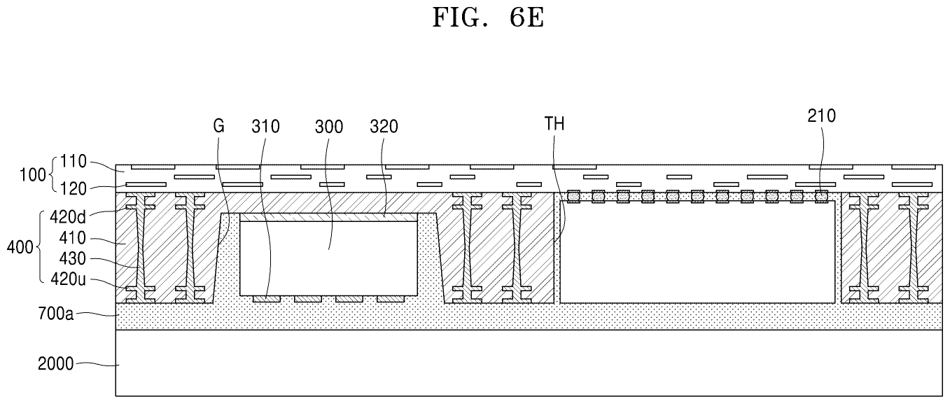

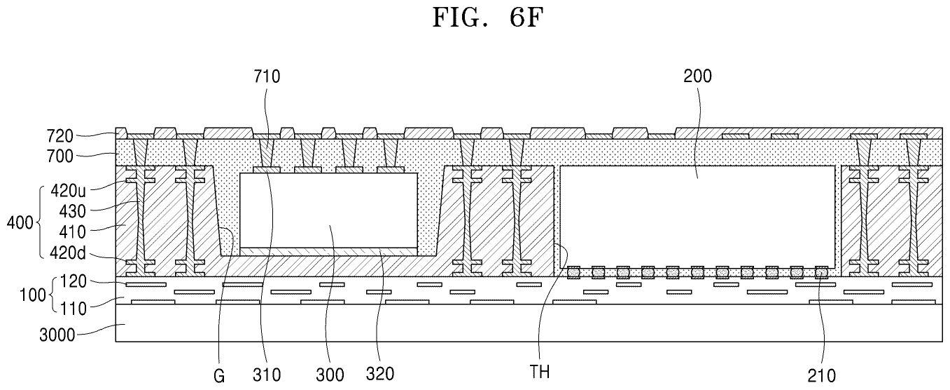

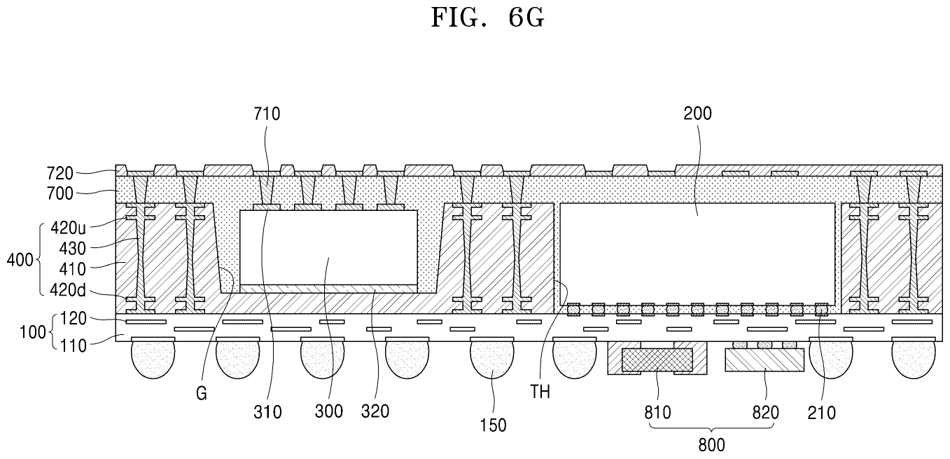

FIGS. 6A to 6G are cross-sectional views schematically illustrating processes of a method of manufacturing a semiconductor package, according to an embodiment.

Referring to FIG. 6A, in the method of manufacturing a semiconductor package according to an embodiment, the first semiconductor device 200 and the second semiconductor device 300 may be prepared. The first semiconductor device 200 may correspond to the first semiconductor device 200 of the semiconductor package 1000 of FIG. 1. In addition, the second semiconductor device 300 may correspond to the second semiconductor device 300 of the semiconductor package 1000 of FIG. 1.

Preparation of the first semiconductor device 200 and the second semiconductor device 300 may be performed in parallel. In other words, the manufacturing processes of the first semiconductor device 200 and the second semiconductor device 300 may be performed independently and without affecting each other. Accordingly, either the first semiconductor device 200 or the second semiconductor device 300 may be manufactured first, or the first semiconductor device 200 and the second semiconductor device 300 may be manufactured together.

As illustrated in FIG. 6A, connection terminals may be disposed on the active surfaces of the first semiconductor device 200 and the second semiconductor device 300. Specifically, the first connection terminals 210 may be disposed on the bottom surface, which is the active surface, of the first semiconductor device 200. In addition, the second connection terminals 310 may be disposed on the top surface, which is the active surface, of the second semiconductor device 300.

Referring to FIG. 6B, the core layer 400 may be formed after the first semiconductor device 200 and the second semiconductor device 300 are prepared. More specifically, first, an initial core layer may be formed on a carrier substrate. For example, a plurality of insulating layers constituting the core insulating layer 410 may be formed on the carrier substrate, and the core vias 430 penetrating the plurality of insulating layers and the core wirings 420 on the plurality of insulating layers may be formed to form the initial core layer.

Subsequently, the through-hole TH penetrating the core insulating layer 410 and a part of the core insulating layer 410 may be removed to form the groove G. Sizes and shapes of the through-hole TH and the groove G may be determined according to sizes and shapes of the first semiconductor device 200 and the second semiconductor device 300. The through-hole TH and the groove G may be formed by a mechanical drill and/or a laser drill. Alternatively, the through-hole TH and the groove G may be formed by a sand blasting method using abrasive particles or a dry etching method using plasma.

The core layer 400 may be formed by forming the through-hole TH and the groove G in the core insulating layer 410. In addition, the through-hole region THA may be defined in the core layer 400 by the through-hole TH, and the groove region GA may be defined in the core layer 400 by the groove G.

Referring to FIG. 6C, after the core layer 400 is formed, the first semiconductor device 200 may be arranged in the through-hole region THA, and the second semiconductor device 300 may be arranged in the groove region GA. The first semiconductor device 200 may be arranged in the through-hole region THA such that the bottom surface, which is the active surface, faces downward. In addition, the second semiconductor device 300 may be arranged in the groove region GA such that the top surface, which is the active surface, faces upward.

A support tape may be disposed on a bottom surface of the through-hole region THA, and the first semiconductor device 200 may be arranged in the through-hole region THA in such a way that the first connection terminals 210 may be attached to the support tape. In addition, the second semiconductor device 300 may be arranged in the groove region GA in such a way that the bottom surface may be attached to the bottom surface of the groove G through the first adhesive layer 320. For reference, the support tape is not illustrated in FIG. 6C.

Referring to FIG. 6D, after the first semiconductor device 200 and the second semiconductor device 300 are arranged in the core layer 400, a first carrier substrate 2000 having a molding material may be attached to the core layer 400. The first carrier substrate 2000 may be attached to a portion in which the through-hole TH and the groove G of the core layer 400 are opened. Attachment of the first carrier substrate 2000 to the core layer 400 may be performed by a thermocompression process. Accordingly, the molding material on the first carrier substrate 2000 may be inserted into the through-hole TH and the groove G. For example, the molding material on the first carrier substrate 2000 may flow into the through-hole TH and the groove G. The molding material may be disposed in a space between the internal wall of the through-hole TH and the first semiconductor device 200, and a space between the internal wall of the groove G and the second semiconductor device 300. For example, the molding material may fill a space between the internal wall of the through-hole TH and the first semiconductor device 200, and a space between the internal wall of the groove G and the second semiconductor device 300. The molding material may be cured to constitute an initial sealant 700a.

Referring to FIG. 6E, thereafter, the first redistribution layer 100 may be formed on the core layer 400 and the first semiconductor device 200. The first redistribution layer 100 may be formed by sequentially forming a plurality of first body insulating layers 110 and forming the first redistribution lines 120 and the vias in the plurality of first body insulating layers 110, respectively.

Referring to FIG. 6F, after the first redistribution layer 100 is formed, a second carrier substrate 3000 may be attached to the first redistribution layer 100, and the first carrier substrate 2000 may be removed. Thereafter, the through electrodes 710, the connection pads, and the passivation layer 720 may be formed in the initial sealant 700a. The connection pads may be exposed through the passivation layer 720. In some embodiments, after the through electrodes 710 are formed, the second redistribution layer (refer to 900 in FIG. 4A) may be separately formed on the sealant 700 instead of the connection pads and the passivation layer 720.

Referring to FIG. 6G, the second carrier substrate 3000 may be removed, and the external connection terminals 150 and the passive element 800 may be disposed on the first redistribution layer 100. Subsequently, the semiconductor package 1000 of FIG. 1 may be completed by mounting the third semiconductor device 500 on the sealant 700 through the third connection terminals 510 and attaching the heat dissipation structure 600 through the second adhesive layer 610.

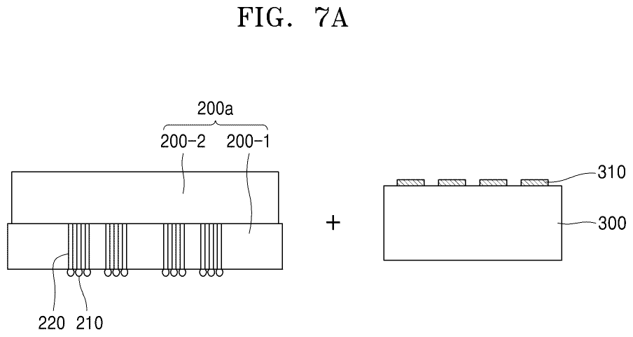

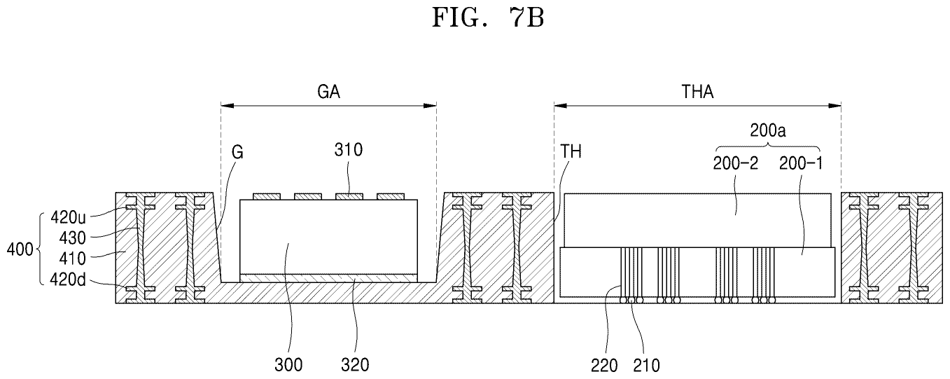

FIG. 7A and FIG. 7B are cross-sectional views schematically illustrating processes of a method of manufacturing the semiconductor package of FIG. 5, according to an embodiment.

Referring to FIG. 7A, in the method of manufacturing a semiconductor package according to an embodiment, the first semiconductor device 200a and the second semiconductor device 300 may be prepared. The first semiconductor device 200a may correspond to the first semiconductor device 200a of the semiconductor package 1000g of FIG. 5. In addition, the second semiconductor device 300 may correspond to the second semiconductor device 300 of the semiconductor package 1000g of FIG. 5.

Preparation of the first semiconductor device 200a and the second semiconductor device 300 may be performed in parallel. In other words, the manufacturing processes of the first semiconductor device 200a and the second semiconductor device 300 may be performed independently, and without affecting each other. In the case of the preparation of the first semiconductor device 200a, after the first semiconductor chip 200-1 and the second semiconductor chip 200-2 are manufactured in parallel, a process of stacking the second semiconductor chip 200-2 on the first semiconductor chip 200-1 may be performed. The process of stacking the second semiconductor chip 200-2 may be performed through bonding using fine bumps, pad-to-pad bonding, HB, or bonding using an ACF.

As illustrated in FIG. 7A, connection terminals may be disposed on the active surfaces of the first semiconductor device 200a and the second semiconductor device 300. Specifically, the first connection terminals 210 may be disposed on the bottom surface, which is the active surface, of the first semiconductor chip 200-1. In addition, the second connection terminals 310 may be disposed on the top surface, which is the active surface, of the second semiconductor device 300.

Referring to FIG. 7B, as described with reference to FIG. 6B, the core layer 400 may be formed after the first semiconductor device 200a and the second semiconductor device 300 are prepared. Thereafter, the first semiconductor device 200a may be arranged in the through-hole region THA, and the second semiconductor device 300 may be arranged in the groove region GA. The first semiconductor device 200a may be arranged in the through-hole region THA such that the bottom surface, which is the active surface, of the first semiconductor chip 200-1, faces downward. In addition, the second semiconductor device 300 may be arranged in the groove region GA such that the top surface, which is the active surface, faces upward.

A support tape may be disposed on a bottom surface of the through-hole region THA, and the first semiconductor device 200a may be arranged in the through-hole region THA in such a way that the first connection terminals 210 may be attached to the support tape. In addition, the second semiconductor device 300 may be arranged in the groove region GA in such a way that the bottom surface may be attached to the bottom surface of the groove G through the first adhesive layer 320. For reference, the support tape is not illustrated in FIG. 7B.

Subsequently, the processes of FIGS. 6D to 6G may be performed to form the semiconductor package 1000g of FIG. 5.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first redistribution layer;
a first semiconductor device disposed on the first redistribution layer;
a second semiconductor device disposed on the first redistribution layer and adjacent to the first semiconductor device;
a support member disposed at side surfaces of the first semiconductor device and the second semiconductor device;
a third semiconductor device disposed above the second semiconductor device; and
a heat dissipation structure disposed above the first semiconductor device and adjacent to the third semiconductor device.

2. The semiconductor package of claim 1, wherein the support member comprises a through-hole region exposing the first redistribution layer, and a groove region including a depression in the support member,
wherein the first semiconductor device is disposed in the through-hole region and the second semiconductor device is disposed in the groove region, and
wherein the support member surrounds the side surfaces of the first semiconductor device and the second semiconductor device.

3. The semiconductor package of claim 2, further comprising:
first connection terminals disposed in the through-hole region and connecting the first semiconductor device to the first redistribution layer; and
second connection terminals disposed in the groove region and connecting the second semiconductor device to the third semiconductor device,
wherein the first semiconductor device comprises a semiconductor chip.

4. The semiconductor package of claim 2, further comprising:
an adhesive layer disposed in the groove region between a bottom surface of the second semiconductor device and the support member; and
wirings penetrating the support member and electrically connecting the first redistribution layer and the third semiconductor device.

5. The semiconductor package of claim 1, wherein the third semiconductor device overlaps at least a part of the first semiconductor device in a vertical direction.

6. The semiconductor package of claim 1, further comprising a second redistribution layer disposed on the first semiconductor device, the second semiconductor device, and the support member, wherein the third semiconductor device and the heat dissipation structure are disposed on the second redistribution layer.

7. The semiconductor package of claim 6, further comprising a sealant disposed on a bottom surface of the second redistribution layer, wherein the sealant covers side surfaces and top surfaces of the first semiconductor device and side surfaces and top surfaces of the second semiconductor device, and
wherein the second semiconductor device is connected to the third semiconductor device through second connection terminals disposed on a top surface of the second semiconductor device and through electrodes connected to the second connection terminals and penetrating the sealant.

8. The semiconductor package of claim 1, wherein the first semiconductor device comprises a first semiconductor chip and a second semiconductor chip, wherein the first semiconductor chip is mounted on the first redistribution layer through first connection terminals disposed on a bottom surface of the first semiconductor chip, and
wherein the second semiconductor chip is disposed on a top surface of the first semiconductor chip.

9. The semiconductor package of claim 8, wherein the first semiconductor chip comprises through chip electrodes connecting the first connection terminals to the second semiconductor chip.

10. The semiconductor package of claim 1, wherein the second semiconductor device comprises a power management IC (PMIC) package, and
wherein the third semiconductor device comprises a memory package including at least one memory chip.

11. The semiconductor package of claim 1, further comprising a passive element disposed on a bottom surface of the first redistribution layer.

12. A semiconductor package comprising:
a first redistribution layer;
a first semiconductor device disposed on the first redistribution layer;
a second semiconductor device disposed on the first redistribution layer and adjacent to the first semiconductor device;
a support member disposed at side surfaces of the first semiconductor device and the second semiconductor device;
a second redistribution layer disposed on the first semiconductor device, the second semiconductor device, and the support member;
a third semiconductor device disposed on the second redistribution layer above the second semiconductor device; and
a heat dissipation structure disposed on the second redistribution layer above at least a part of the first semiconductor device and adjacent to the third semiconductor device, wherein the support member comprises a through-hole region exposing the first redistribution layer, and a groove region including a depression in the support member, and
wherein the first semiconductor device is disposed in the through-hole region and the second semiconductor device is disposed in the groove region.

13. The semiconductor package of claim 12, wherein the first semiconductor device comprises a semiconductor chip, wherein the first semiconductor device is directly mounted on the first redistribution layer through first connection terminals disposed on a bottom surface of the first semiconductor device, and
wherein the second semiconductor device is connected to the second redistribution layer through second connection terminals disposed on a top surface of the second semiconductor device.

14. The semiconductor package of claim 13, further comprising a sealant disposed on a bottom surface of the second redistribution layer, wherein the sealant covers side surfaces and top surfaces of the first semiconductor device and side surfaces and top surfaces of the second semiconductor device, and
wherein through electrodes connected to the second connection terminals and penetrating the sealant are disposed in the sealant.

15. The semiconductor package of claim 12, wherein the first semiconductor device comprises a first semiconductor chip and a second semiconductor chip, wherein the first semiconductor chip is mounted on the first redistribution layer through first connection terminals disposed on a bottom surface of the first semiconductor chip, and
wherein the second semiconductor chip is disposed on a top surface of the first semiconductor chip.

16. The semiconductor package of claim 12, further comprising a passive element disposed on a bottom surface of the first redistribution layer,
wherein the second semiconductor device comprises a power management IC (PMIC) package, and
wherein the third semiconductor device comprises a memory package including at least one memory chip.

17. A semiconductor package comprising:
a first redistribution layer;
a first semiconductor device disposed on the first redistribution layer;
a second semiconductor device disposed on the first redistribution layer and adjacent to the first semiconductor device;
a support member including a through-hole region in which the first semiconductor device is disposed and a groove region in which the second semiconductor device is disposed;
a third semiconductor device disposed above the second semiconductor device; and
a heat dissipation structure disposed above at least a part of the first semiconductor device and adjacent to the third semiconductor device, wherein the through-hole region exposes the first redistribution layer, and
wherein the groove region including a depression in the support member and having a width that increases as a distance from the support member increases.

18. The semiconductor package of claim 17, wherein the first semiconductor device comprises a semiconductor chip, wherein the first semiconductor device is directly mounted on the first redistribution layer through first connection terminals disposed on a bottom surface of the first semiconductor device, and
wherein the second semiconductor device is connected to the third semiconductor device through second connection terminals disposed on a top surface of the second semiconductor device.

19. The semiconductor package of claim 17, further comprising a second redistribution layer disposed on the first semiconductor device, the second semiconductor device, and the support member, wherein the third semiconductor device and the heat dissipation structure are disposed on the second redistribution layer.

20. The semiconductor package of claim 17, wherein the first semiconductor device comprises a first semiconductor chip and a second semiconductor chip, wherein the first semiconductor chip is disposed on the first redistribution layer through first connection terminals disposed on a bottom surface of the first semiconductor chip, and
wherein the second semiconductor chip is disposed on a top surface of the first semiconductor chip.
